(19) United States
(12) Patent Application Publication
(10) Pub. No.: US 2013/0017316 A1
(43) Pub. Date: Jan. 17, 2013

(54) SPUTTER GUN

(71) Applicants: Hong Sheng Yang, Pleasanton, CA (US); Kent Riley Child, Dublin, CA (US)

(72) Inventors: Hong Sheng Yang, Pleasanton, CA (US); Kent Riley Child, Dublin, CA (US)

(73) Assignee: INTERMOLECULAR, INC., San Jose, CA (US)

(21) Appl. No.: 13/184,291

(22) Filed: Jul. 15, 2011

(51) Int. Cl. C23C 14/54; C23C 14/35

(52) U.S. Cl. 427/8; 118/620; 118/663; 118/712; 427/598

(57) ABSTRACT

A sputter gun is provided in the embodiments contained herein. The sputter gun includes an impeller disposed within a backside portion of an opening within a housing of the sputter gun, the housing including an inlet directing fluid to rotate the impeller around an axis. A plate is disposed next to the impeller, the plate has openings extending therethrough, the openings enabling the fluid access to a backside portion of the opening within the housing. A plurality of magnets is disposed within the front side of the plate and extending from a surface of the plate such that as the impeller rotates with the plurality of magnets. A thermally conductive membrane extends across a front surface of the front portion of the opening, wherein the fluid contacts the thermally conductive membrane prior to exiting the opening within the housing. A method of performing a deposition process is also included.

### TECHNICAL FIELD

The present disclosure generally relates to the field of apparatus for thin-film processing on a substrate and more particularly to sputter deposition gun.

### BACKGROUND

Physical vapor deposition is commonly used within the semiconductor industry, as well as solar, glass coating, and other industries, in order to deposit a layer over a substrate. Sputtering is a common physical vapor deposition method, where atoms or molecules are ejected from a target material by high-energy particle bombardment and then deposited onto the substrate.

Erosion of the target during the processing operations occurs in an uneven manner when the magnetic field remains stationary during the sputtering process. The uneven erosion of the target leads to shortened target life and requires frequent changing of the target, which incurs unnecessary costs. Localized heating at target erosion grooves can cause target cracking or even melting. The cooling of the target during processing continues to be a challenge in the production environment, as well as the research and development environment. Any improvements to the cooling capability enable a higher deposition rate to be achieved, due to the increased power enabled through the enhanced cooling capabilities. Thus, current sputter guns, especially relatively smaller sized sputter guns, suffer from uneven erosion and have limited deposition rates at low process power due to the inability to adequately cool the sputter guns.

In order to evaluate different materials, different unit processes (e.g. process conditions or parameters), or different sequencing and integration of processes, and combinations thereof, it may be desirable to be able to process different regions of the substrate differently. This capability (hereinafter called “combinatorial processing”) typically employs relatively smaller sized sputter guns when combinatorially evaluating a sputtering process. Thus, what is needed is a sputter gun that erodes evenly and can achieve a relatively high deposition rate.

It is within this context that the current embodiments arise.

### SUMMARY

Embodiments of the present invention provide a sputter gun in which the magnetron is rotated by the flow of the cooling fluid to ensure even erosion of the target and wherein the cooling capability is enhanced. Several inventive embodiments of the present invention are described below.

In one aspect of the invention, a sputter gun is provided. The sputter gun includes an impeller disposed within a backside portion of an opening in a housing of the sputter gun, the housing including an inlet directing fluid to rotate the impeller around an axis. A plate is disposed next to the impeller, the plate has openings extending therethrough, the openings enabling the fluid access to a backside portion of the opening within the housing. A plurality of magnets is disposed within the front side of the plate and extending from a surface of the plate such that the impeller rotates with the plurality of magnets. A thermally conductive membrane extends across a front surface of the front portion of the opening, wherein the fluid contacts the thermally conductive membrane prior to exiting the opening within the housing. In one embodiment, a sensor detecting erosion of a target surface is provided in order to control the movement, in a direction perpendicular to the rotational movement, of the plate where the magnets are mounted so that a distance between a surface of a target and the front surface of the magnets remains substantially constant during erosion of the target.

In another aspect of the invention, a deposition method is provided. The method initiates with imparting rotational movement to a plurality of magnets through a fluid flow applied to the sputter gun. The method includes dissipating heat generated from a target of the sputtering gun during operation through the fluid flow applied to the sputter gun. In one embodiment, the method includes sensing erosion of a surface of the target in-situ, and moving the plurality of magnets in a direction perpendicular to the rotational movement to maintain a substantially constant distance from the surface of the target being eroded to a planar surface shared by the plurality of magnets.

Other aspects of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings. Like reference numerals designate like structural elements.

FIG. 1 is a simplified schematic diagram illustrating a prior-art sputter gun.

FIG. 2A is a simplified schematic diagram illustrating a rotating magnetron sputter gun having enhanced cooling capabilities and uniform target erosion control in accordance with one embodiment of the invention.

FIG. 2B illustrates a flow path of the fluid to drive the impeller and cool the target in accordance with one embodiment of the invention.

FIG. 3 is a top view of an impeller in accordance with one embodiment of the invention.

FIG. 4 is a top view of magnetron assembly in accordance with one embodiment of the invention.

### DETAILED DESCRIPTION

The embodiments described herein provide a method and apparatus related to high deposition rate sputter gun. It will be obvious, however, to one skilled in the art, that the present invention may be practiced without some or all of these specific details. In other instances, well known process operations have not been described in detail in order not to unnecessarily obscure the present invention.

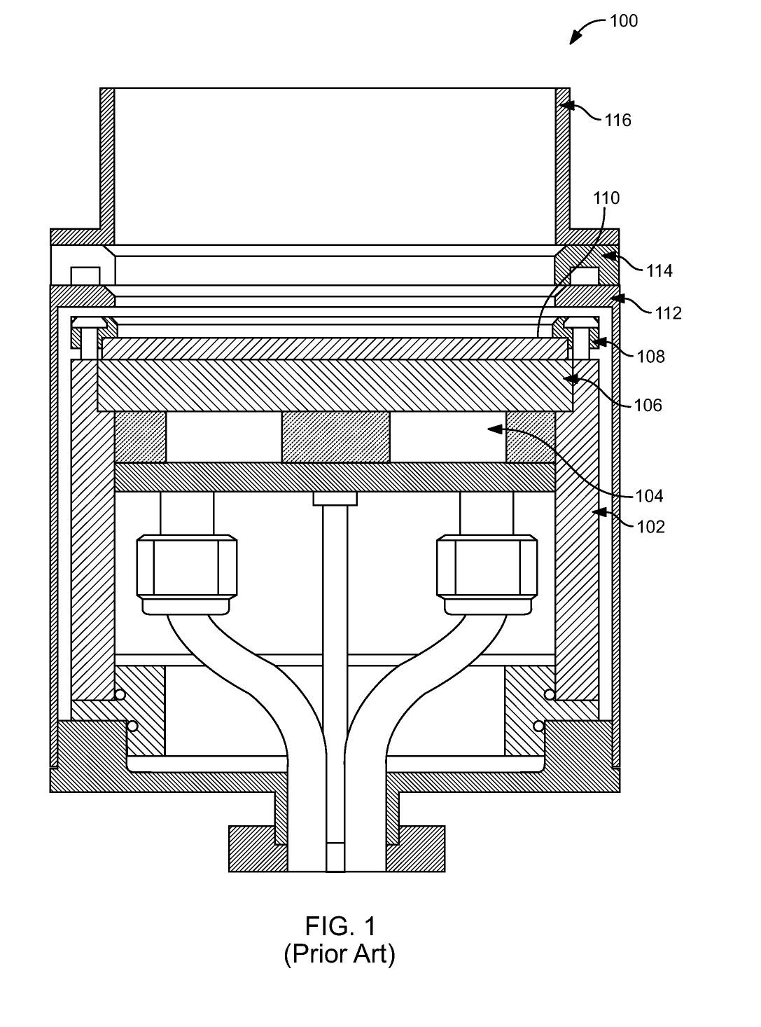

FIG. 1 is a simplified schematic diagram of a prior art sputter gun. Sputter gun 100 includes a housing 102 supporting magnet array 104 disposed below cooling well 106. Hold down ring 108 supports target 110. Dark space shield 112 is provided below an optional gas injection ring 114 and optional deposition chimney 116. The prior art sputter gun of FIG. 1 is prone to non-uniform target erosion and short target life.

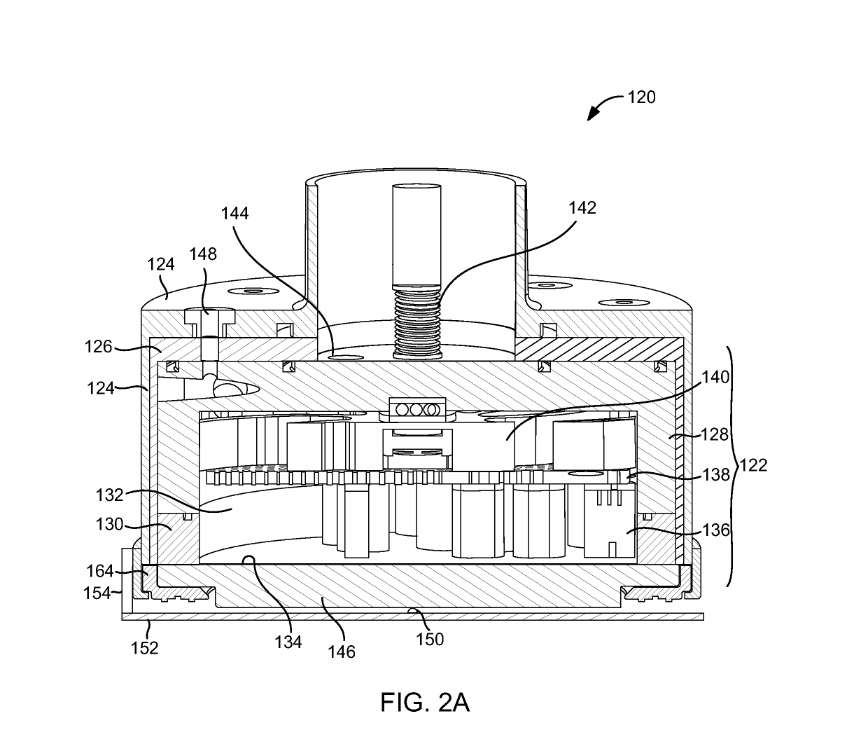

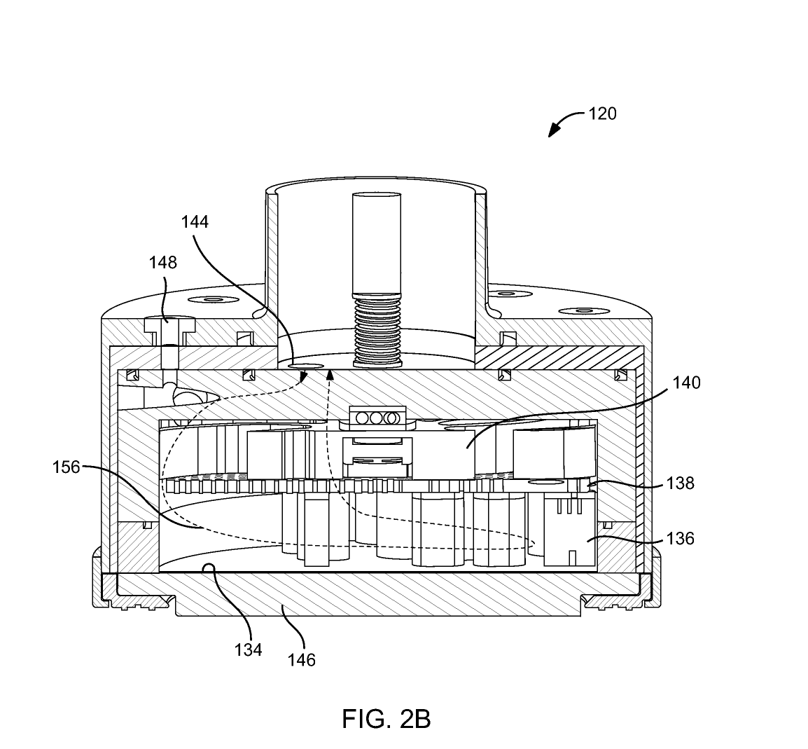

FIG. 2A is a simplified schematic diagram illustrating a rotating magnetron sputter gun having enhanced cooling capabilities and improved target erosion uniformity in accordance with one embodiment of the invention. Sputter gun 120 includes a housing 122 having multiple layers of components. The multiple layers of components includes ground shield 124 which encapsulates the side surfaces and a majority of a backside surface of the sputter gun. In one embodiment, ground shield 124 is composed of stainless steel, however, any suitable conductive, but non-ferromagnetic, material may be utilized for the ground shield. Ground shield 124 is disposed over ceramic insulator 126. Ceramic insulator 126 is disposed over jacket 128 and jacket 130. It should be appreciated that while jacket 128 and jacket 130 are illustrated as two different materials, the jackets may be constructed from a single material as a monolithic jacket. In one embodiment, jacket 128 is composed of stainless steel, while jacket 130 is composed of copper. Opening 132 is defined by jackets 128 and 130, and membrane 134 and the opening contains magnets 136, plate 138, and impeller 140. A centrally located opening on a backside surface of sputter gun 120 provides access for shaft 142, which is coupled to impeller 140. In one embodiment, plate 138 is made of ferromagnetic material, e.g., magnetic stainless steel, to shunt the magnet field from the magnets 136, and is sometimes called a “shunt plate”.

In one embodiment, shaft 142 is coupled to impeller 140 utilizing thrust plate bearings and a pneumatic control. One skilled in the art will appreciate that the thrust plate bearings and pneumatic control are configured to relieve pressure of a clutch in order to disengage the rotation of impeller 140 from driving, or rotating, plate 138 and magnets 136. In an exemplary embodiment the rotations per minute (RPM) control assembly is a swash plate. One skilled in the art will appreciate that a swash plate translates the motion of a rotating shaft into reciprocating motion, or a reciprocating motion into a rotating one. In this embodiment, pulling up on shaft 142 will disengage the coupling of impeller 140 to plate 138. Thus, the fluid flow may still drive impeller 140, however, the rotational motion is not imparted to plate 138 due to this disengagement.

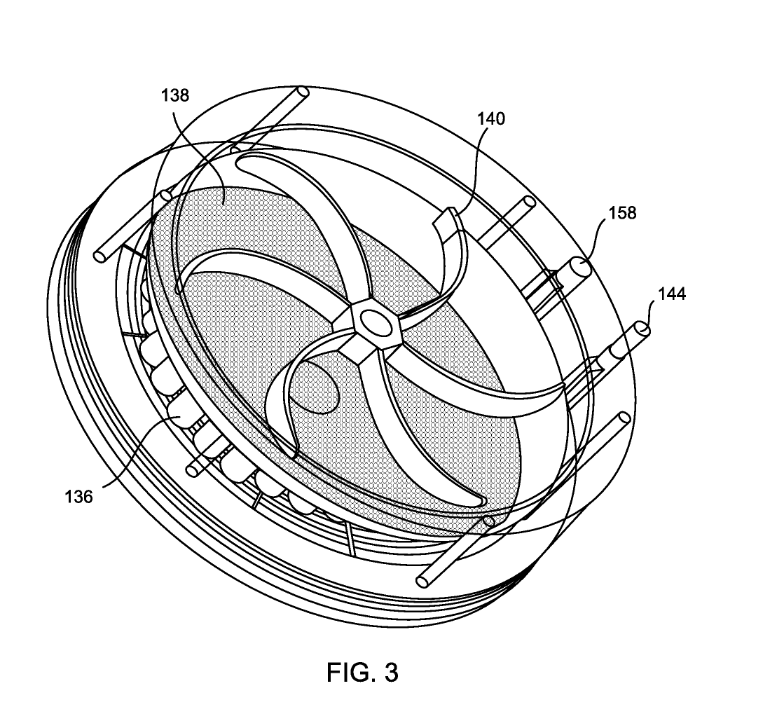

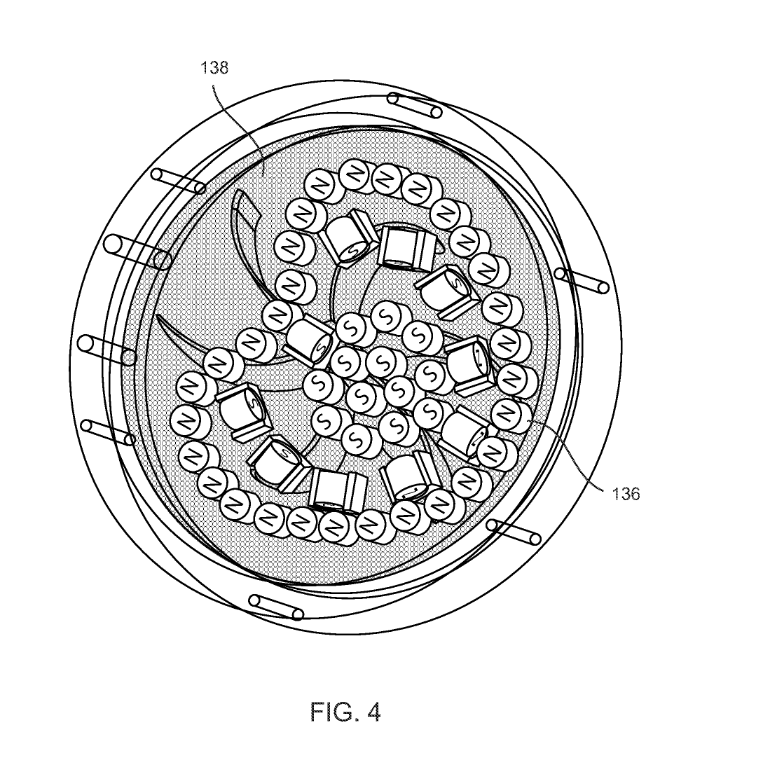

Still referring to FIG. 2A, impeller 140 has a plurality of blades extending from a central region. The blades extending outward of impeller 140 may be curved or straight. Fluid flow through inlet 144 provides the force necessary to rotate impeller 140. Impeller 140 functions as a directional pump in one embodiment so that the fluid flows toward a periphery of the opening 132 within the housing 122 from a back portion to a front portion of the opening 132. The fluid flow proceeds through openings extending through plate 138 into the front portion of the opening 132 and contacts membrane 134 prior to exiting through an outlet opening 158 (illustrated in FIG. 3) defined within proximity to opening 132. Thus, in one embodiment, the fluid flow can be analogized to a vortex pattern in the opening 132 of the housing 122. Magnets 136 are affixed to a bottom surface of plate 138. Thus, as plate 138 rotates magnets 136 will also rotate. In one embodiment, magnets 136 are asymmetrically disposed about an axis of rotation for plate 138 and impeller 140, as shown in FIG. 4. This embodiment assists in achieving a substantially even erosion pattern across a surface of target 146 during sputtering operations. A front surface of magnets 136 is disposed above a back surface of membrane 134. Membrane 134 is relatively thin, e.g., within a range of about 5 to 20 thousandths of an inch. Membrane 134 may be a thermally conductive membrane composed of a thoroughly conductive material, such as copper. One skilled in the art will appreciate that alternative thermally conductive materials may be utilized for membrane 134 with the embodiments described herein. It should be further appreciated that the fluid flow across membrane 134 removes the heat generated by target 146 during the processing. Target 146 is supported against a surface of membrane 134 and jacket 130 in one embodiment. Other means of affixing may be utilized to secure target 146. It should be noted that due to the relative thinness of membrane 134, the membrane conforms to any irregularities on the surface of target 146 facing a front surface of the membrane. Membrane 134 also efficiently transfers heat generated by target 146 to the fluid utilized for imparting the rotational motion to impeller 140 and flowing over a back surface of membrane 134. In one embodiment the fluid is water, however, alternative fluids may be utilized with the embodiments described herein. The thickness of membrane 134 is less than 20/1000 of an inch, however, thicker membranes may be incorporated with the embodiments described herein.

The rotational velocity of impeller 140 of FIG. 2A may be controlled through an audio sensor 148 disposed within sputter gun 120. Audio sensor 148 may be configured to sense a frequency for the water flowing out of sputter gun 120. The frequency can be tuned to capture the water flowing out as each blade of impeller 140 interrupts the water flow coming from the backside portion of the opening 132 to an outlet 158 proximate to opening 132. A controller, e.g., a computing device in communication with sensor 148, can be configured to divide the number of times the blades interrupt the outward flow of the fluid in a time period by the number of blades on impeller 140, in order to arrive at the rotations per minute of the impeller. One skilled in the art will appreciate that alternative sensing methods may be employed to capture the rotational velocity of the impeller. The controller may also control a pump or other fluid source and increase or decrease the flow rate of the fluid into sputter gun 120 to achieve the desired rotations per minute for impeller 140, which in turn controls the rotation of the magnets 136. It should be appreciated that the movement of magnets 136 enable the even erosion of target 146 during a sputtering process.

Still referring to FIG. 2A, sputter gun 120 provides a mechanism and structure for the in situ measurement of the target thickness. Sensor 150 is disposed on the inner surface of gun shutter 152. In one embodiment, gun shutter 152 pivots around a pivot point of side extension 154 to enclose target 146 to prevent deposition of material sputtered from another target in the same sputter chamber onto target 146. In closed position, gun shutter is typically 2-20 mm from target 146. Sensor 150 is configured to detect the surface of target 146 as gun shutter 152 pivots to open and close. Thus, sensor 150 radially scans the erosion surface of target 146. It should be appreciated that alternatives to side extension 154 may be utilized as a mount for gun shutter 152. For example, gun shutter 152 may be coupled to an arm supporting sputter gun 120. Sensor 150 communicates with a computing device that processes the captured data and determines target thickness or the amount of erosion that has taken place on the surface of target 146. In response to the diminishing thickness of target 146, plate 138 may be moved away from target 146. This is often called “Z-position adjustment”. It should be appreciated that the Z-position adjustment of plate 138 may be achieved through shaft 142 which is coupled to a drive in communication with the computing device. In one embodiment, each time gun shutter 152 is opened and/or closed the scanning of the surface of target 146 is performed and the distance between the surface of the target being eroded and the magnets may be adjusted by moving plate 138 in a Z-direction orthogonal to the plane of the rotation of impeller 140.

FIG. 2B illustrates a flow path of the fluid to drive the impeller and cool the target in accordance with one embodiment of the invention. The fluid pathway is illustrated by line 156 through sputter gun 120. Fluid enters through inlet opening 144 and is directed to force rotation of impeller 140. Impeller 140 forces the fluid that is driving the impeller through openings in plate 138 from the back region to the front region of sputter gun 120. It should be appreciated that the openings within plate 138 may be defined through holes extending through the plate so that the plate is a porous plate. Magnets 136 force water in the front region of sputter gun 120 against a surface of membrane 134. A pressure difference caused by the rotational forces in sputter gun 120 forces the fluid from the front region of the sputter gun to a central region of the sputter gun and then to an outlet opening 158 in a backside of the sputter gun in one embodiment. As mentioned above, the sonic pressure may be monitored through audio sensor 148 in order to control the rotation speed of impeller 140. It should be appreciated that magnets 136 distribute the fluid in a substantially even manner across a surface of membrane 134. In addition, a pressure associated with the fluid in the front region of the gun provides a force to maintain the contact between membrane 134 and a surface of target 146 for efficient heat transfer. In one embodiment, the rotational forces essentially create a vortex defined by fluid path 156 that drives impeller 140 and transfers heat from target 146. The fluid exits sputter gun housing 122 at an outlet 158.

FIG. 3 is a top view of an impeller in accordance with one embodiment of the invention. Impeller 140 is driven by the fluid entering inlet 144. As discussed above, the fluid drives impeller 140 and is forced through the opening of plate 138 to a lower chamber where magnets 136 are housed. The fluid provides a heat transfer mechanism so that heat from the target is efficiently transferred across a membrane contacting a backside of the target to the fluid flowing across the opposing surface of the membrane.

FIG. 4 is a top view of magnetron assembly in accordance with one embodiment of the invention. Magnets 136 are disposed below a surface of plate 138. The orientation of magnets 136 is an exemplary orientation and not meant to be limiting. In FIG. 4, the outer magnet track consists of magnets pieces with north pole facing a sputter target whereas the inner magnet track consists of magnets with the south pole facing sputter target. The magnetic polarity can be reversed as long as the inner and outer tracks have opposing magnetic polarities. A larger number of magnet pieces of smaller sizes or a smaller number of magnet pieces of larger sizes may be included to achieve the desired magnetic field strength. The cross section of magnet pieces can be circular, square, rectangle, or other shapes. The ratio of height to the cross section dimension of the magnet pieces can range from 1:1 to 3:1.

As shown in FIG. 4, the profile of the magnet piece arrangement is such that the resulting erosion on the target is relatively uniform when the magnet is rotating during sputtering. Uniform target erosion will not only help improve target utilization, but also minimize uneven plasma heating. Profiled magnets can also be used, instead of the cylindrical pieces shown in FIG. 4, to obtain the desired shape of outer and inner magnet tracks for achieving uniform target erosion. To further increase magnetic field strength, the gaps between the inner and outer magnet tracks can be filled with lateral magnet pieces which produce parallel magnetic fields on a target surface, being superimposed the magnetic field produced by the inner and outer magnetic tracks of opposing polarities. Stronger magnetic fields allow the use of a thicker target, which is especially important in case of a target made of ferromagnetic material as a thin target will result in frequent target change and increased tool down time.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims. In the claims, elements and/or steps do not imply any particular order of operation, unless explicitly stated in the claims.

What is claimed is:

1. A sputter gun, comprising:
a housing having an opening with a first portion and a second portion;
an impeller disposed within the first portion of the opening, the housing having an inlet directing fluid to rotate the impeller around a central axis of the impeller;
a plate disposed below the impeller, the plate having openings extending therethrough, the openings enabling the fluid access to the second portion of the opening;
a plurality of magnets disposed within the second portion of the opening and extending from a surface of the plate such that the impeller rotates the plurality of magnets about the axis; and
a thermally conductive membrane extending across a bottom surface of the second portion of the opening, wherein the fluid contacts the thermally conductive membrane prior to exiting the opening.

2. The sputter gun of claim 1, wherein the plurality of magnets are asymmetrically disposed around the axis.

3. The sputter gun of claim 1 wherein the impeller is removably coupled to the plate.

4. The sputter gun of claim 1, further comprising:
a shaft extending into the first portion of the opening, the shaft coupled to the impeller and the plate, the shaft configured to move the plate in a direction orthogonal to a plane of rotation of the impeller.

5. The sputter gun of claim 1, further comprising:
an audio sensor detecting a frequency associated with the fluid exiting the sputter gun, wherein data captured by the audio sensor controls a rotational velocity of the impeller.

6. The sputter gun of claim 1, wherein the sputter gun is one of a plurality of sputter guns disposed within a processing chamber.

7. The sputter gun of claim 1, wherein the thermally conductive membrane is a metal and has a thickness of less than 20 thousandths of an inch.

8. A sputter gun, comprising;
an impeller configured to rotate about an axis in response to a fluid flow applied thereto;
a plate disposed under the impeller and removably attached to the impeller, the plate having openings extending therethrough, the openings enabling the fluid access to pass through the plate, the plate configured to move in a vertical direction within a housing of the sputter gun and configured to rotate about the axis as the impeller rotates;
a plurality of magnets affixed to a bottom surface of the plate;
a target affixed to a surface of a membrane extending across a bottom surface of the housing; and
a sensor configured to detect erosion of a surface of the target.

9. The sputter gun of claim 8, wherein the plurality of magnets are asymmetrically disposed around the axis.

10. The sputter gun of claim 8, further comprising;
an audio sensor detecting a frequency associated with the fluid flow exiting the sputter gun, wherein data captured by the audio sensor controls a rotational velocity of the impeller.

11. The sputter gun of claim 8, wherein an inner surface of the housing has a stainless steel upper portion disposed over a copper lower portion.

12. The sputter gun of claim 8, wherein the membrane is a flexible thin film that is thermally conductive.

13. The sputter gun of claim 12, wherein the membrane is composed of copper and has a thickness of less than 20 thousandths of an inches.

14. The sputter gun of claim 8, wherein the sensor is disposed on a surface of a gun shutter pivotably mounted to the sputter gun.

15. A method for operating a sputter gun, comprising:
imparting rotational movement to a plurality of magnets through a fluid flow applied to the sputter gun; and
removing heat generated from a target during operation of the sputter gun through the fluid flow applied to the sputter gun.

16. The method of claim 15 further comprising;
sensing erosion of a surface of the target in-situ; and
moving the plurality of magnets in a direction orthogonal to the rotational movement to maintain a substantially constant distance from the surface of the target to a planar surface shared by the plurality of magnets.

17. The method of claim 15, further comprising:
detecting a frequency of the fluid flow exiting the sputter gun; and
adjusting a rotational velocity of the plurality of magnets in response to the detecting the frequency.

18. The method of claim 15, wherein the removing heat is performed through a membrane disposed between the fluid flow and the target.

19. The method of claim 16, wherein the sensing comprises;
scanning a surface of the target upon opening or closing a gun shutter.

20. The method of claim 15, wherein the imparting comprises:
directing the fluid flow toward blades of an impeller coupled to the plurality of magnets.
